(19) United States
(12) Patent Application Publication
(10) Pub. No.: US 2023/0199957 A1
(43) Pub. Date: Jun. 22, 2023

(54) MULTILAYER SUBSTRATE AND MANUFACTURING METHOD THEREFOR

(71) Applicant: Zhuhai ACCESS Semiconductor Co., Ltd., Guangdong (CN)

(72) Inventors: Xianming CHEN, Guangdong (CN); Lei FENG, Guangdong (CN); Benxia HUANG, Guangdong (CN); Yejie HONG, Guangdong (CN)

(21) Appl. No.: 17/906,853

(22) PCT Filed: Jul. 24, 2020
(86) PCT No.: PCT/CN2020/104572

§ 371 Date: Sep. 20, 2022

(30) Foreign Application Priority Data
Jun. 17, 2020 (CN) 202010551905.3

(51) Int. Cl. H05K 1/11; H05K 3/00; H05K 3/18; H05K 3/46

(52) U.S. Cl. CPC H05K 1/115; H05K 3/0047; H05K 3/0076; H05K 3/188; H05K 3/4658; H05K 2201/096; H05K 2201/09545; H05K 2203/061; H05K 2203/0723; H05K 2203/167

(57) ABSTRACT

A multilayer substrate and a manufacturing method thereof are disclosed. The multilayer substrate includes two or more dielectric layers laminated in sequence; a public line disposed at a top or bottom dielectric layer of the two or more dielectric layers; and two or more first through hole pillars respectively each embedded in a respective one of the dielectric layers, and the first through hole pillars are connected in cascade and then connected with the public line.

### CROSS-REFERENCE TO RELATED APPLICATIONS

This application is a national stage filing under 35 U.S.C. § 371 of international application number PCT/CN2020/104572, filed Jul. 24, 2020, which claims priority to Chinese patent application No. 2020105519053 filed Jun. 17, 2020. The contents of these applications are incorporated herein by reference in their entirety.

### TECHNICAL FIELD

The disclosure relates to the technical field of circuit boards, and more particularly, to a multilayer substrate and a manufacturing method thereof.

### BACKGROUND

With the development of electronic technology, structures of electronic components are becoming more and more complex, and requirements on miniaturization, integration and heat dissipation effects are getting higher and higher. At present, in the industry, circuits at different layers of a multilayer board are connected through a plated through hole or a copper pillar. One of the widely used manufacturing technologies for creating inter-layer interconnection holes is laser drilling. The drilled holes penetrate through a dielectric substrate arranged in the following to the last metal layer, and then are filled with metal, which is generally copper, and is deposited in the holes by plating technology. This hole-forming method is sometimes called “drilling-filling”, and the resulting through hole may be called “drilling-filling through hole”.

Due to the positioning limitation in the existing technology, the position of a through hole can only be controlled within 10 microns from a corresponding position, and due to the limitation of laser drilling, there is a minimum size limitation for the through hole, i.e., about 50-60 microns for its diameter. When making holes or copper pillars and lines, due to the limitation of alignment accuracy between layers, it is required that conducted lines expand a ring width outward to form a Pad, so as to avoid bad line connection between layers. For circuit boards with limited areas, the more pads, the smaller the wiring area of transmission lines such as power supply and signal transmission. In order to realize the miniaturization of the circuit board, the current method therefor is to reduce sizes of the line and the hole or copper pillar, which leads to the decline of signal transmission performance and heat dissipation effect of products.

### SUMMARY

The disclosure aims at solving at least one of the technical problems in the existing technology. Therefore, the disclosure provides a multilayer substrate, which can omit a Pad and increase an available wiring area of a transmission line.

In a first aspect, a multilayer substrate according to an embodiment of the disclosure includes two or more of dielectric layers laminated in sequence; a public line disposed at a top or bottom dielectric layer of the two or more dielectric layers; and two or more first through hole pillars each embedded in a respective one of the dielectric layers. The first through hole pillars are connected in cascade and then connected with the public line.

The multilayer substrate according to an embodiment of the disclosure at least has the following beneficial effects.

For a public line of non-source power and signal transmission, the first through hole pillars are connected in cascade and then connected with the public line, which can omit the Pad connected between the first through hole pillars, and prevent the Pad from occupying the wiring area of the circuit board, thus increasing the available wiring area of the transmission line.

According to some embodiments of the disclosure, a first seed layer is arranged between the first through hole pillars of adjacent layers, and/or a second seed layer is arranged between the first through hole pillar and the public line.

According to some embodiments of the disclosure, the first seed layer and the second seed layer are made of at least one material selected from a group consisting of Ni, Au, Cu or Pd.

According to some embodiments of the disclosure, a first adhesion metal layer is arranged between the first seed layer and the dielectric layer, and/or, a second adhesion metal layer is arranged between the second seed layer and the dielectric layer.

According to some embodiments of the disclosure, the first adhesion metal layer and the second adhesion metal layer are made of at least one material selected from a group consisting of Ti, Ta, W, Ni, Cr, Pt, Al or Cu.

According to some embodiments of the disclosure, a projection shape of the first through hole pillar in an X-Y plane is circular or square.

In a second aspect, a manufacturing method of a multilayer substrate according to an embodiment of the disclosure includes:

S100: selecting an initial layer, and manufacturing a first line layer with a first line pattern on the initial layer;

S200: manufacturing a first through hole layer on the initial layer and the first line layer, where the first through hole layer includes a first through hole pillar and a second through hole pillar, the first through hole pillar is arranged in a trench of the first line pattern, and the second through hole pillar is arranged on the first line pattern;

S300: laminating a dielectric material on the first through hole layer to obtain a semi-stack, and thinning the semi-stack to expose end portions of the first through hole pillar and the second through hole pillar, and using the end portion of at least one of the first through hole pillar or the second through hole pillar as a positioning mark for alignment;

S400: separating the semi-stack from the initial layer;

S500: selecting the semi-stack as a new initial layer, and repeating S100 and S300 to form two or more layers, where the first through hole pillar of the semi-stack of each layer is connected in cascade with the first through hole pillar of the semi-stack of a previous layer, and the second through hole pillar of the semi-stack of each layer is connected with the first line pattern of the semi-stack of next layer; and

S600: manufacturing a second line layer with a second line pattern on an outer surface of the semi-stack of a last layer, where the second line pattern includes a public line and a transmission line, the first through hole pillar of the semi-stack of the last layer is connected with the public line, and the second through hole pillar of the semi-stack of the last layer is connected with the transmission line.

The manufacturing method of a multilayer substrate according to an embodiment of the disclosure at least has the following beneficial effects.

According to the manufacturing method of the embodiment of the disclosure, the end portion of at least one of the first through hole pillar or the second through hole pillar is used as the positioning mark for alignment, so that the alignment accuracy can be improved; the first through hole pillar of the semi-stack of each layer is connected with the first through hole pillar of the semi-stack of the previous layer, and the second through hole pillar of the semi-stack of each layer is connected with the line pattern of the semi-stack of next layer, so that after the multilayer substrate is formed, the first through hole pillars from different layers are connected in cascade and then connected with the public line, which can omit the Pad connected between the first through hole pillars of different layers, thus increasing the available wiring area of the transmission line.

According to some embodiments of the disclosure, S100 includes:

S110: selecting the initial layer;

S120: manufacturing the first seed layer on the initial layer;

S130: machining a first photoresist layer on the first seed layer;

S140: exposing and developing the first photoresist layer to form a first feature pattern;

S150: electroplating metal in the first feature pattern to form the first line layer; and

S160: removing the first photoresist layer.

According to some embodiments of the disclosure, S200 includes:

S210: machining a second photoresist layer on the initial layer and the first line layer;

S220: exposing and developing the second photoresist layer to form a second feature pattern;

S230: electroplating metal in the second feature pattern to form the first through hole layer; and

S240: removing the second photoresist layer.

According to some embodiments of the disclosure, S120 includes:

S121: manufacturing a first adhesion metal layer on the initial layer; and

S122: manufacturing the first seed layer on the first adhesion metal layer.

Additional aspects and advantages of the disclosure will be given in part in the following description, and will become apparent in part from the following description, or will be learned through the practice of the disclosure.

### BRIEF DESCRIPTION OF THE DRAWINGS

The above and/or additional aspects and advantages of the disclosure will be more apparent from the following description of the embodiments in conjunction with the accompanying drawings, where:

FIG. 1 is a schematic diagram showing structural comparison between a multilayer substrate according to an embodiment of the disclosure and a multilayer substrate in the existing technology;

FIG. 2 is a schematic structural diagram of an initial layer of a first layer of the multilayer substrate according to an embodiment of the disclosure;

FIG. 3 is a schematic structural diagram of a first seed layer of the first layer of the multilayer substrate according to an embodiment of the disclosure;

FIG. 4 is a schematic structural diagram of a first line layer of the first layer of the multilayer substrate according to an embodiment of the disclosure;

FIG. 5 is a schematic structural diagram of a first through hole layer of the first layer of the multilayer substrate according to an embodiment of the disclosure;

FIG. 6 is a schematic structural diagram of a dielectric layer of the first layer of the multilayer substrate according to an embodiment of the disclosure;

FIG. 7 is a schematic structural diagram of the first layer of the multilayer substrate according to an embodiment of the disclosure;

FIG. 8 is a schematic structural diagram of a first line layer of a second layer of the multilayer substrate according to an embodiment of the disclosure;

FIG. 9 is a schematic structural diagram of a second photoresist layer of the second layer of the multilayer substrate according to an embodiment of the disclosure;

FIG. 10 is a schematic structural diagram of a first through hole layer of the second layer of the multilayer substrate according to an embodiment of the disclosure;

FIG. 11 is a schematic structural diagram of a dielectric layer of the second layer of the multilayer substrate according to an embodiment of the disclosure;

FIG. 12 is a schematic structural diagram of a fourth photoresist layer of the second layer of the multilayer substrate according to an embodiment of the disclosure; and

FIG. 13 is a schematic structural diagram of a second line layer of the second layer of the multilayer substrate according to an embodiment of the disclosure.

### DETAILED DESCRIPTION

The embodiments of the disclosure will be described in detail hereinafter. Examples of the embodiments are shown in the accompanying drawings. The same or similar reference numerals throughout the drawings denote the same or similar elements or elements having the same or similar functions. The embodiments described below with reference to the accompanying drawings are exemplary and are only intended to explain the disclosure, but should not be construed as limiting the disclosure.

In the description of the disclosure, the orientation or positional relationship indicated by the terms upper, lower, X, Y, Z and the like is based on the orientation or positional relationship shown in the drawings, only for the convenience of describing the disclosure and simplifying the description, and does not indicate or imply that the indicated device or element must have a specific orientation, or be constructed and operated in a specific orientation. Therefore, the terms should not be construed as limiting the disclosure.

In the description of the disclosure, the meaning of several or multiple refers to be two or more, and the meanings of greater than, less than, more than, etc., are understood as not including the subsequent number, while the meanings of above, below, within, etc., are understood as including the subsequent number. If there is a description to the first and second, it is only for the purpose of distinguishing between technical features, and shall not be understood as indicating or implying relative importance, implicitly indicating the number of the indicated technical features or implicitly indicating the order of the indicated technical features.

In the description of the disclosure, unless otherwise specified, words such as setting, connecting, and the like, should be understood broadly, and those of ordinary skills in the art can reasonably determine the specific meanings of the above words in the disclosure in combination with the specific contents of the technical solutions.

The following description relates to a support structure composed of metal through holes in a dielectric matrix, especially copper through hole pillars in a polymer matrix, such as glass fiber reinforced polyimide, epoxy resin or BT (bismaleimide/triazine) or mixtures thereof.

Whether there is an effective upper limit for an in-plane dimension of a feature structure is a feature of photoresist and pattern or panel plating and laminating technology of Access Company, as described in U.S. Pat. Nos. 7,682,972, 7,669,320 and 7,635,641 of Hurwitz et al., which are incorporated herein by reference.

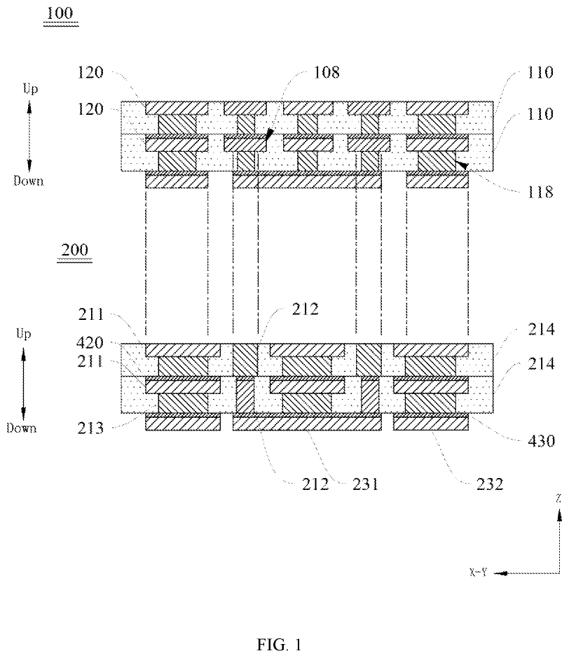

Referring to FIG. 1, which is a diagram showing cross-sectional comparison between a multilayer substrate in the existing technology and a multilayer substrate according to an embodiment of the disclosure. The multilayer substrate 100 of the existing technology includes functional layers 120 of components or feature structures 108 that are isolated by dielectric layers 110 for insulating between layers. A through hole 118 passing through the dielectric layer 214 provides electrical connection between adjacent functional or feature layers. Therefore, a feature structure layer 120 includes a feature structure 108 (i.e., the Pad mentioned in the background section above) that is usually laid in a layer on an X-Y plane, and a through hole 118 that conducts current across the dielectric layers 110. The through holes 118 are designed to have the minimum inductance and are sufficiently isolated to have the minimum capacitance therebetween.

Referring to FIG. 1, a multilayer substrate 200 disclosed in the embodiment of the disclosure includes two or more dielectric layers 214. The dielectric layers 214 are located in an X-Y plane, and the two or more dielectric layers 214 are laminated in sequence in a Z-axis direction to form a three-dimensional structure. After laminating, the dielectric layer 214 at a top or at a bottom is provided with a public line 231. In this embodiment, the public line 231 is a line used for non-source power or signal transmission. The multilayer substrate 200 further includes two or more first through hole pillars 212. The two or more first through hole pillars 212 are embedded in the corresponding dielectric layers 214 respectively, and are connected in cascade and then connected with the public line 231.

From the comparison of FIG. 1, it can be seen that for the public line 231 of the non-source power and signal transmission, the first through hole pillars 212 are connected in cascade and then connected with the public line, which can omit Pad connected between the first through hole pillars 212, and has at least the following beneficial effects:

1. beneficial to improve the integration of lines and the signal transmission density;

2. avoiding the Pad occupying a wiring area of a circuit board, making more room for the transmission line 232 of power supply or signal transmission, increasing a line width of the transmission line 232, increasing a size of the through hole or the through hole pillar, improving the heat dissipation performance of the product, and reducing a resistance value and voltage drop of a loop to a certain extent; and

3. omitting the Pad, which improves the space utilization rate for wiring of the circuit board and can promote the miniaturization of the product to some extent.

In the production process, in order to improve a bonding force between the first through hole pillars 212 of adjacent layers, a first seed layer 420 is arranged between the first through hole pillars 212 of adjacent layers, or in order to improve the bonding force between the first through hole pillars 212 and the public line 231, a second seed layer 430 is arranged between the first through hole pillar 212 and the public line 231. The first seed layer 420 and the second seed layer 430 may be arranged simultaneously. That is, in order to improve the bonding force between the first through hole pillars 212 of adjacent layers and the bonding force between the first through hole pillar 212 and the public line 231, the first seed layer 420 is arranged between the first through hole pillars 212 of adjacent layers, and the second seed layer 430 is arranged between the first through hole pillar 212 and the public line 231. Specifically, a material of the first seed layer 420 and the second seed layer 430 is at least one of Ni, Au, Cu or Pd, and the first seed layer 420 and the second seed layer 430 may be deposited by sputtering or electroless plating.

In order to facilitate the first seed layer 420 to adhere to the dielectric layer 214 of the previous layer, a first adhesion metal layer is further arranged between the first seed layer 420 and the dielectric layer 214. Alternatively, in order to facilitate the second seed layer 430 to adhere to the dielectric layer 214 of the previous layer, a second adhesion metal layer is further arranged between the second seed layer 430 and the dielectric layer 214. The first adhesion metal layer and the second adhesion metal layer may be arranged at the same time. That is, when the first seed layer 420 and the second seed layer 430 are arranged at the same time, the first seed layer 420 adheres to the first adhesion metal layer and the second seed layer 430 adheres to the second adhesion metal layer, respectively. Specifically, a material of the first adhesion metal layer and the second adhesion metal layer is at least one of Ti, Ta, W, Ni, Cr, Pt, Al or Cu. The first adhesion metal layer and the second adhesion metal layer may be deposited by physical vapor deposition (PVD) or electroless plating.

When the through holes are manufactured by using a drilling-filling technology, the through holes usually have a substantially circular cross section, because the through holes are manufactured by drilling laser holes in the dielectric first. Because the dielectric is heterogeneous and anisotropic, and is composed of a glass fiber reinforced polymer matrix containing an inorganic filler, the circular cross section of the dielectric is usually rough at edges and the cross section of the dielectric may slightly deviate from a true circle. In addition, the through holes often have a certain degree of taper, that is, reverse truncated cone instead of cylinder. By using the “drilling-filling through hole” method, it is impossible to manufacture non-circular holes because of the difficulties in section control and shape.

The embodiment of the disclosure utilizes the flexibility of plating and photoresist technology to economically and effectively manufacture through holes with a wide range of shapes and sizes, and in addition, and can manufacture through holes with different shapes and sizes in the same layer. A through hole pillar method developed by AMITEC in the patent thereof can realize the “conductor through hole” structure with large-size through hole layer conducting electricity in the X-Y plane. This is particularly advantageous when a copper pattern plating method is used. Smooth, straight and non-tapered trenches can be generated in the photoresist material, and then filled by depositing copper in these trenches with a metal seed layer, and then filled by pattern plating copper in these trenches. Different from the drilling-filling through hole method, the through hole pillar technology can fill the trenches in the photoresist layer to obtain copper connections with fewer dents and bumps. After depositing copper, the photoresist is lifted off, then the metal seed layer is removed and a permanent polymer-glass dielectric is coated on and around the metal seed. The resulting “through hole conductor” structure can use the process flow as described in U.S. Pat. Nos. 7,682,972 7,669,320 and U.S. Pat. No. 7,635,641 of Hurwitz et al. Therefore, this embodiment can realize that a projection shape of the first through hole pillar 212 in the X-Y plane is circular or square.

An embodiment of the disclosure further discloses a manufacturing method of a multilayer substrate, where some manufacturing steps, such as the addition, exposure, development and subsequent removal steps of photoresist are not discussed in detail here, because the materials and technological processes in these steps are well-known technologies. To be exact, those of ordinary skills in the art can make appropriate choices for the manufacturing process and materials according to some parameters such as specifications, substrate complexity, components, etc. In the following description, um is equivalent to μm and micron, and 1 um=10⁻⁶ m (meter). The manufacturing method of a multilayer substrate according to an embodiment of the disclosure includes the following steps.

At S100, an initial layer is selected, and a first line layer 211 with a first line pattern is manufactured on the initial layer; specifically, the step S100 including the following steps.

At S110, the initial layer is selected.

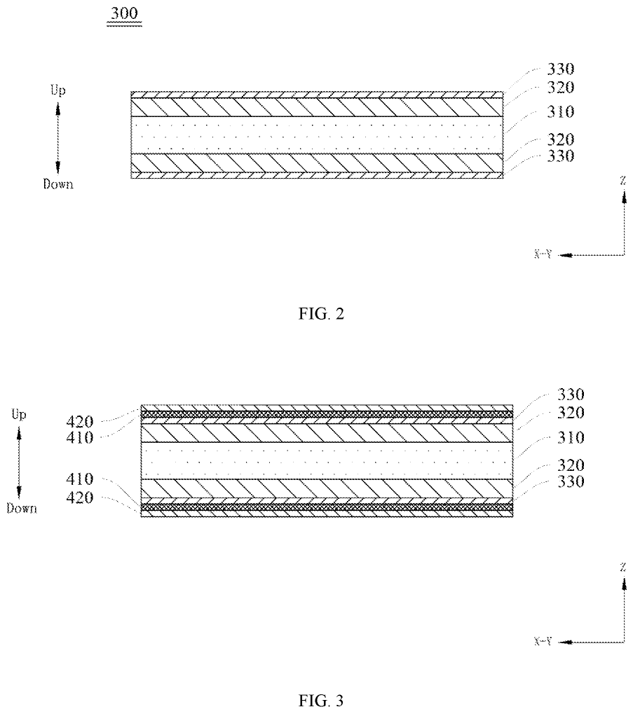

Referring to FIG. 2, this embodiment uses a double-sided copper foil 300 as the initial layer, the double-sided copper foil 300 includes a base layer 310, 18 um copper foils 320 respectively covering upper and lower surfaces of the base layer 310, and 3 um copper foils 330 each covering a surface of a respective one of the 18 um copper foils 320.

At S120, A first seed layer 420 is manufactured on the initial layer, where the step S120 specifically includes the following steps.

At S121, a first adhesion metal layer 410 is manufactured on the initial layer.

Referring to FIG. 3, this embodiment refers to double-sided manufacturing, and the first adhesion metal layer 410 is deposited on the upper and lower surfaces of the double-sided copper foil 300. In some embodiments, the first adhesion metal layer 410 may be deposited by physical vapor deposition (PVD) or electroless plating, and a material of the first adhesion metal layer 410 is at least one of Ti, Ta, W, Ni, Cr, Pt, Al or Cu, and the first adhesion metal 410 facilitates the adhesion of the subsequent first seed layer 420 to the initial layer.

At S122, continuously referring to FIG. 3, the first seed layer 420 is manufactured on the first adhesion metal layer 410.

In some embodiments, the first seed layer 420 may be deposited by sputtering or electroless plating, and a material of the first seed layer 420 is at least one of Ni, Au, Cu or Pd.

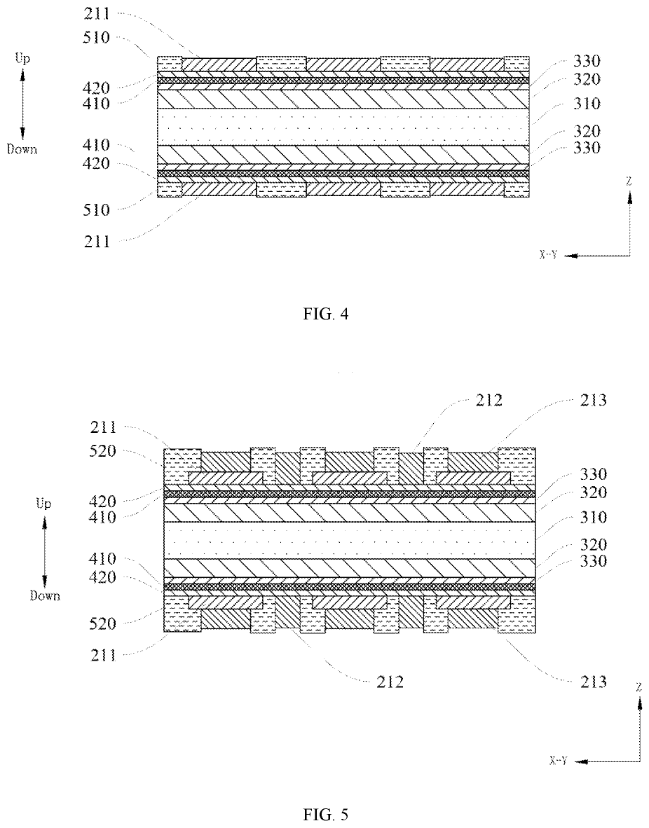

At S130: referring to FIG. 4, a first photoresist layer 510 is processed on the first seed layer 420.

At S140, referring to FIG. 4, the first photoresist layer 510 is exposed and developed to form a first feature pattern.

At S150, referring to FIG. 4, metal is electroplated in the first feature pattern to form the first line layer 211.

At S160, the first photoresist layer 510 is removed and an upright first line pattern is remained, where the first line pattern refers to a metal line, usually a copper line, which is manufactured according to production data and has an electrical signal transmission function. Trenches are provided between adjacent copper lines to meet the requirements of electrical spacing.

At S200, referring to FIG. 5, a first through hole layer is manufactured on the initial layer and the first line layer 211, where the first through hole layer includes a first through hole pillar 212 and a second through hole pillar 213, the first through hole pillar 212 is arranged in a trench of the first line pattern, and the second through hole pillar 213 is arranged on the first line pattern.

Referring to FIG. 5, the step S200 specifically includes the following steps of:

S210: machining a second photoresist layer 520 on the initial layer and the first line layer 211;

S220: exposing and developing the second photoresist layer 520 to form a second feature pattern;

S230: electroplating metal in the second feature pattern to form the first through hole layer; and

S240: removing the second photoresist layer 520.

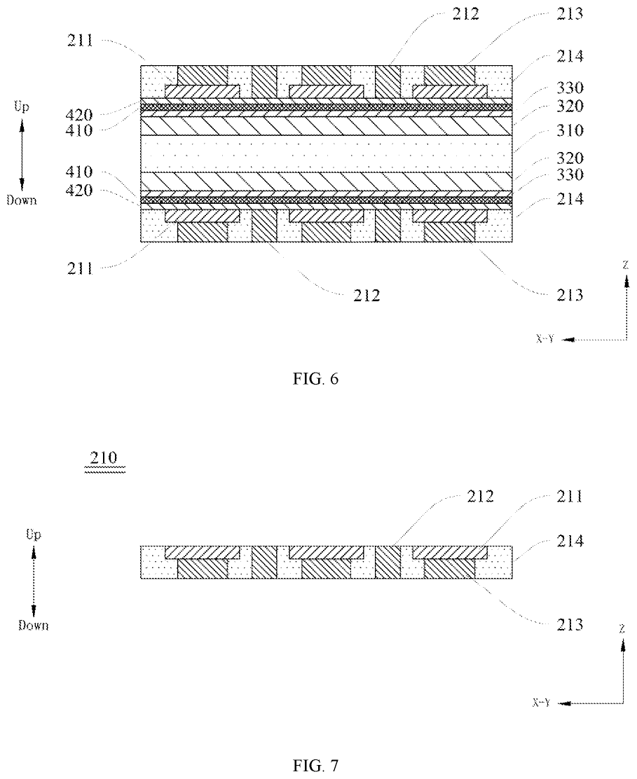

At S300, referring to FIG. 6, a dielectric material is laminated on the first through hole layer to form a dielectric layer 214 to obtain a semi-stack, and the semi-stack is thinned to expose end portions of the first through hole pillar 212 and the second through hole pillar 213, and using the end portion of at least one of the first through hole pillar 212 or the second through hole pillar 213 as a positioning mark for alignment.

The semi-stack of this embodiment includes the first line layer 211, the first through hole layer and the dielectric layer 214 surrounding the first line layer 211 and the first through hole layer. Thinning the semi-stack can be accomplished by mechanical grinding or polishing or Chemical Mechanical Polishing (CMP). Thinning can also flatten the semi-stack, which is convenient for the subsequent construction of additional layers and accurate alignment, where the end portion of at least one first through hole pillar 212 or second through hole pillar 213 is used as the positioning mark for alignment, which is conducive to improving the alignment accuracy, the principle of which has been disclosed in the existing technology, such as U.S. Pat. No. 1,353,1948 of Hurwitz et al., which is incorporated herein by reference in its entirety. The improvement of the alignment accuracy in combination with the cascade connecting structure of the first through hole pillars 212, can omit the Pad between the first through hole pillars 212 of adjacent layers.

At S400, referring to FIG. 6 and FIG. 7, the semi-stack and the initial layer are separated, where the semi-stack and the initial layer can be separated by the existing circuit board layering device and process, and will not be described again in this embodiment. The semi-stack obtained by separation is the first layer 210 of the multilayer substrate.

At S500, the semi-stack separated in the step S400 is selected as a new initial layer, and the steps S100 and S300 are repeated to form two or more layers, where the first through hole pillar of the semi-stack of each layer is connected with the first through hole pillar of the semi-stack of the previous layer in cascade, and the second through hole pillar 213 of the semi-stack of each layer is connected with the first line pattern of the semi-stack of next layer.

Specifically, the following will take the manufacturing process of a second layer of the multilayer substrate as an example. The step S500 includes the following steps of:

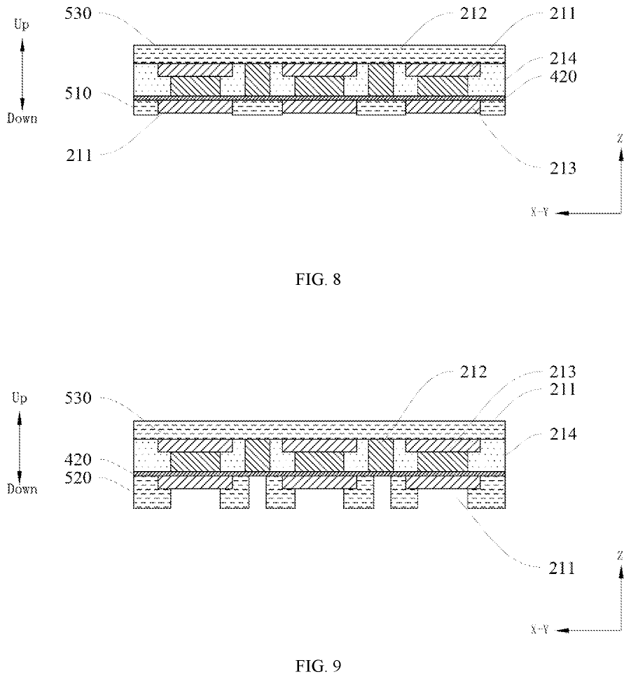

S511: referring to FIG. 8, selecting the semi-stack separated from the initial layer as a new initial layer according to the step S110, where this embodiment relates to single-sided manufacturing, so a third photoresist layer 530 is processed on a first side of the semi-stack;

S512: manufacturing the first seed layer 420 on a second side of the semi-stack according to the step S120, where the first side of the semi-stack is the side close to the first line pattern, and the second side is opposite to the first side. It should be noted that in order to facilitate the first seed layer 420 to adhere to the semi-stack of the previous layer, the first adhesion metal layer is also deposited on the semi-stack, and the first seed layer 420 adheres to the first adhesion metal layer;

S513: processing the first photoresist layer 510 on the first seed layer 420 generated in the step S512 according to the step S130;

S514: exposing and developing the first photoresist layer 510 generated in the step S513 according to the step S140 to form a first feature pattern;

S515: electroplating metal in the first feature pattern generated in the step S514 according to the step S150 to form the first line layer 211; and

S516: removing the first photoresist layer 510 generated in the step S514 according to the step S160, and remaining the upright first line pattern.

At S521, referring to FIG. 9, the second photoresist layer 520 is processed on the initial layer and the first line layer 211 generated in the step S515 according to the step S210.

At S522, the second photoresist layer 520 generated in the step S521 according to the step S220 is exposed and developed to form a second feature pattern.

At S523, metal is electroplated in the second feature pattern generated in the step S522 according to the step S230 to form the first through hole layer.

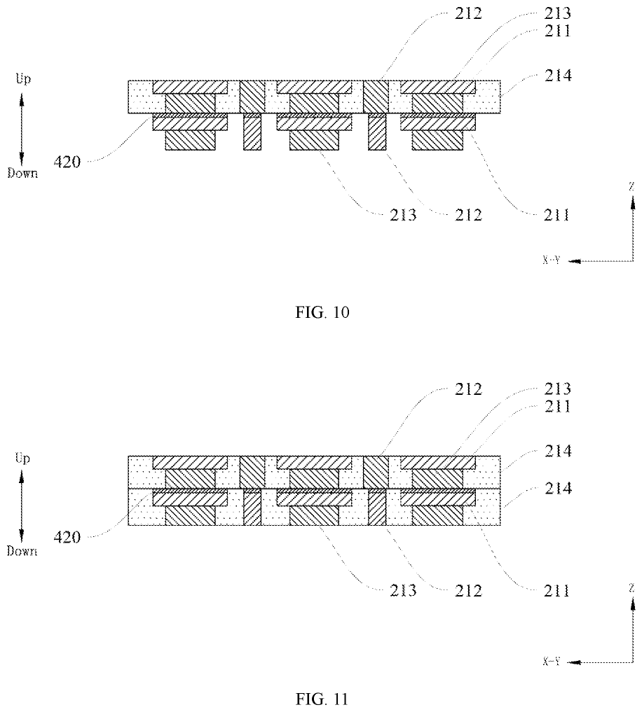

At S524, referring to FIG. 10, the second photoresist layer 520 generated in the step S522 is removed according to the step S240, where in this embodiment, the second photoresist layer 520 is soaked and removed by a photoresist cleaning solution. Therefore, in this step, the third photoresist 530 generated in the step S511 is also removed, and the first seed layer 420 generated in the step S512 is etched after the second photoresist layer 520 is removed.

At S530, referring to FIG. 11, a dielectric material is laminated on the first through hole layer generated in the step S523 according to the step S300 to form the dielectric layer 214 to obtain a semi-stack of the second layer, so as to manufacture the second layer of the multilayer substrate, and the semi-stack of the second layer is thinned to expose the end portions of the first through hole pillar 212 and the second through hole pillar 213, and the end portion of at least one of the first through hole pillar 212 or the second through hole pillar 213 is used as the positioning mark for alignment.

At S540, the steps S100˜S300 are repeated by analogy until the manufacturing of each layer of the multilayer substrate is completed.

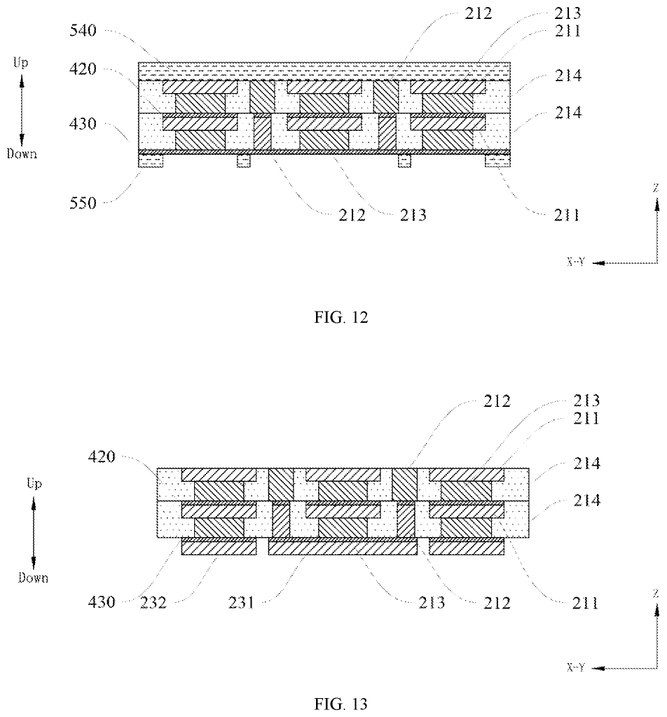

At S600, referring to FIG. 12 and FIG. 13, a second line layer is manufactured on an outer surface of the semi-stack of the last layer. The second line layer includes the public line 231 and the transmission line 232. The first through hole pillar 212 of the semi-stack of the last layer is connected with the public line 231, and the second through hole pillar 213 of the semi-stack of the last layer is connected with the transmission line 232.

In order to improve a bonding force of the second line layer with the first through hole pillar 212 and the second through hole pillar 213, the step S600 specifically includes the following steps.

At S610, referring to FIG. 12, this embodiment takes single-sided manufacturing as an example, so after a fourth photoresist layer 540 is processed on a surface of the semi-stack of the first layer, a second adhesion metal layer is deposited on a lower surface of the semi-stack of the last layer, where the second adhesion metal layer may be deposited by physical vapor deposition or electroless plating, and a material of the second adhesion metal layer is at least one of Ti, Ta, W, Ni, Cr, Pt, Al or Cu.

At S620, generating a second seed layer 430 on the second adhesion metal layer, where the second seed layer 430 may be deposited by sputtering or electroless plating, and a material of the second seed layer 430 is at least one of Ni, Au, Cu or Pd.

At S630, a fifth photoresist layer 550 is processed on the second seed 430.

At S640, the fifth photoresist layer 550 is exposed and developed to form a new third feature pattern.

At S650, metal is electroplated in the third feature pattern to form the second line layer.

At S660, the fourth photoresist layer 540 and the fifth photoresist layer 55 are removed, and the second seed layer 430 is etched.

According to the manufacturing method of the embodiment of the disclosure, the end portion of at least one of the first through hole pillar 212 or the second through hole pillar 213 is used as the positioning mark for alignment, so that the alignment accuracy can be improved; the first through hole pillar of the semi-stack of each layer is connected with the first through hole pillar of the semi-stack of the previous layer, and the second through hole pillar of the semi-stack of each layer is connected with the first line pattern of the semi-stack of next layer, so that after the multilayer substrate is formed, the first through hole pillars 212 between different layers are connected with the public line 231 in cascade, which can omit the Pad connected between the first through hole pillars 212 of different layers, thus increasing the available wiring area of the transmission line 232.

For the production method of the semi-stack, the embodiments of the disclosure are only illustrative. In the known various varying production methods, such as the known panel plating instead of pattern plating, those of ordinary skills in the art will recognize that the disclosure is not limited to what is specifically illustrated and described above.

The embodiments of the disclosure are described in detail with reference to the drawings above, but the disclosure is not limited to the above embodiments, and various changes may also be made within the knowledge scope of those of ordinary skills in the art without departing from the purpose of the disclosure.

1. A multilayer substrate, comprising:
a plurality of dielectric layers laminated in sequence;
a public line disposed at a top or bottom dielectric layer of the plurality of dielectric layers; and
a plurality of first through hole pillars each embedded in a respective one of the dielectric layers, wherein the first through hole pillars, which are connected in cascade, are connected with the public line.

2. The multilayer substrate according to claim 1, wherein a first seed layer is arranged between the first through hole pillars of adjacent layers, and/or a second seed layer is arranged between the first through hole pillar and the public line.

3. The multilayer substrate according to claim 2, wherein the first seed layer and the second seed layer are made of at least one material selected from a group consisting of Ni, Au, Cu or Pd.

4. The multilayer substrate according to claim 2, wherein a first adhesion metal layer is arranged between the first seed layer and the dielectric layer, and/or, a second adhesion metal layer is arranged between the second seed layer and the dielectric layer.

5. The multilayer substrate according to claim 4, wherein the first adhesion metal layer and the second adhesion metal layer are made of at least one material selected from a group consisting of Ti, Ta, W, Ni, Cr, Pt, Al or Cu.

6. The multilayer substrate according to claim 1, wherein a projection shape of the first through hole pillar in an X-Y plane is circular or square.

7. A manufacturing method of a multilayer substrate, comprising:
S100: selecting an initial layer, and manufacturing a first line layer with a first line pattern on the initial layer;
S200: manufacturing a first through hole layer on the initial layer and the first line layer, wherein the first through hole layer comprises a first through hole pillar and a second through hole pillar, the first through hole pillar is arranged in a trench of the first line pattern, and the second through hole pillar is arranged on the first line pattern;
S300: laminating a dielectric material on the first through hole layer to obtain a semi-stack, and thinning the semi-stack to expose end portions of the first through hole pillar and the second through hole pillar, and using the end portion of at least one of the first through hole pillar or the second through hole pillar as a positioning mark for alignment;
S400: separating the semi-stack from the initial layer;
S500: selecting the semi-stack as a new initial layer, and repeating S100 and S300 to form a plurality of layers, wherein the first through hole pillar of the semi-stack of each layer is connected in cascade with the first through hole pillar of the semi-stack of a previous layer, and the second through hole pillar of the semi-stack of each layer is connected with the first line pattern of the semi-stack of next layer; and
S600: manufacturing a second line layer with a second line pattern on an outer surface of the semi-stack of a last layer, wherein the second line pattern includes a public line and a transmission the first through hole pillar of the semi-stack of the last layer is connected with the public and the second through hole pillar of the semi-stack of the last layer is connected with the transmission line.

8. The manufacturing method of a multilayer substrate according to claim 7, wherein S100 comprises:
S110: selecting the initial layer;
S120: manufacturing the first seed layer on the initial layer;
S130: machining a first photoresist layer on the first seed layer;
S140: exposing and developing the first photoresist layer to form a first feature pattern;
S150: electroplating metal in the first feature pattern to form the first line layer; and
S160: removing the first photoresist layer.

9. The manufacturing method of a multilayer substrate according to claim 7, wherein S200 comprises:
S210: machining a second photoresist layer on the initial layer and the first line layer;
S220: exposing and developing the second photoresist to form a second feature pattern;
S230: electroplating metal in the second feature pattern to form the first through hole layer; and
S240: removing the second photoresist layer.

10. The manufacturing method of a multilayer substrate according to claim 8, wherein S120 comprises:
S121: manufacturing a first adhesion metal layer on the initial layer; and
S122: manufacturing the first seed layer on the first adhesion metal layer.
